(19) United States
(12) Patent Application Publication
(10) Pub. No.: US 2004/0036131 A1
(43) Pub. Date: Feb. 26, 2004

(54) Electrostatic discharge protection devices having transistors with textured surfaces

(75) Inventors: Warren M. Farnworth, Nampa, ID (US); Lucien J. Bissey, Boise, ID (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 10/226,678

(22) Filed: Aug. 23, 2002

(51) Int. Cl. H01L 29/76

(52) U.S. Cl. 257/409

(57) ABSTRACT

An electrostatic discharge (ESD) protection device connects to a bonding pad and an internal circuit for protecting the internal circuit during an ESD event. The ESD protection device includes a transistor connected between the bonding pad and a supply node. The transistor includes a first doped region having a textured surface connected to the bonding pad, and a second doped region having a textured surface connected to the supply node.

### FIELD

The present invention relates generally to semiconductor devices, and in particular to electrostatic discharge protection devices.

### BACKGROUND

Semiconductor devices such as transistors are widely used as switches in electrical circuits to control the flow of current. Many circuits use transistors to protect them from an electrostatic discharge (ESD) event. An ESD event occurs when an external voltage much higher than the normal operating voltage of the circuit appears at bonding pads or external pins of the circuit. Human or other elements could cause the ESD event. Without a protection device, a large ESD current and the heat created by the ESD event could flow from the bonding pad to internal elements of the circuit and potentially damage these internal elements.

FIG. 1 is a cross-section of a conventional transistor 100 having a substrate 102, a source 104, a drain 106, a gate 108. Transistor 100 has linear dimensions D1, D2, and D3. Source and drain 104 and 106 have surfaces S1, S2. As shown in FIG. 1, surfaces S1 and S2 are and flat.

When transistor 100 serves as a conventional ESD protection device, source 104 connects to a bonding pad 110, drain connects to a voltage V1, and gate 108 connects to a voltage V2. Source 104 also connects to an internal circuit 112. In a normal condition (non-ESD event), a negligible or no current flows between substrate 102, source 104, and drain 106. In an ESD event, the ESD current from bonding pad 110 discharges to substrate 102, thereby protecting internal circuit 112 from potential damage.

Transistor 100 is normally constructed with specified D1, D2, and D3 such that S1 and S2 have adequate surface areas to allow the ESD current to sufficiently discharge when transistor 100 serves as an ESD protection device. Many ESD protection devices are larger than a normal transistor. In some cases, one way to reduce total size of the circuit having transistor 100 is to reduce D1, D2 and D3. However, reducing D1, D2, and D3 also reduces S1 and S2. When transistor 100 serves as an ESD protection device, the reduced S1 and S2 may not be adequate for the ESD current to discharge. This may damage transistor 100 itself or cause it to protect the circuit inadequately.

### SUMMARY OF THE INVENTION

The present invention provides transistors and diodes having reduced linear dimensions (or reduced sized) to save space while maintaining adequate surface areas so that when these transistors and diodes are used as ESD protection devices, they provide sufficient protection. Further, the reduced sized transistors and diodes allow the bonding pads to be smaller. Thus, size of the circuit having these transistors, diodes, and bonding pads can be made smaller, or more components can be added to the circuit without increasing the size of the circuit.

In a first aspect, a transistor includes a substrate, a first doped region formed in the substrate, and a second doped region formed in the substrate. Each of the first and second doped regions includes a textured surface.

In a second aspect, a protection device includes a substrate, a first well and a second well formed in the substrate. A first doped region and a second doped region are formed in the first well. The first doped region includes a textured surface connected to a first supply contact. The second doped region includes a textured surface connected to a bonding contact. A third doped region and a fourth doped region are formed in the second well. The third doped region includes a textured surface connected to the bonding contact. The fourth doped region includes a textured surface connected to a second supply contact.

In a third aspect, a method of making a transistor includes forming a first doped region and a second doped region in a substrate. Each of the first and second doped regions has an exposed surface. The method further includes texturing the exposed surface to increase its surface area.

In a fourth aspect, a method of making a device includes forming a first well and a second well in a substrate. A first doped region and a second doped region are formed in the first well. Each of the first and second doped regions has an exposed surface. A third doped region and a fourth doped region are formed in the second well. Each of the third and fourth doped regions has an exposed surface. The method further includes texturing the exposed surfaces of all the doped regions to increase their surface areas. After the exposed surfaces are textured, they become textured surfaces. A bonding contact is formed on the textured surfaces of second and third dopes regions to connect the second and third dopes regions. A first supply contact is formed on the textured surface of the first doped region. A second supply contact is formed on the exposed textured surface of the fourth doped region. Because the exposed surfaces are textured, the contact surfaces between the doped regions and the bonding and supply contacts increase. When the contact surfaces increase, the amount of current passing through these surfaces also increases. Further, when the contact surfaces increase, the contact resistance decreases, thereby allowing more heat to dissipate.

### BRIEF DESCRIPTION OF THE DRAWINGS

FIG. 1 is a cross-section of a conventional transistor.

FIG. 2 is a cross-section of a bipolar transistor having a textured surface according to an embodiment of the invention.

FIG. 3 is an isometric view of the textured surface of the transistor of FIG. 2.

FIG. 4A is a cross-section of a diode having a textured surface according to an embodiment of the invention.

FIG. 4B is a cross-section of gated transistor having a textured surface according to another embodiment of the invention.

FIG. 4C is a cross-section of a floating gate transistor having a textured surface according to another embodiment of the invention.

FIGS. 5-9 show examples of textured surfaces according to various embodiments of the invention.

FIG. 10A is a cross-section of an ESD protection device having transistors with textured surfaces according to an embodiment of the invention.

FIG. 10B is a cross-section of an ESD protection device having reverse biased diodes with textured surfaces according to an embodiment of the invention.

FIG. 10C is a cross-section of another ESD protection device having transistors with textured surfaces according to another embodiment of the invention.

FIG. 11 shows an integrated circuit having the ESD protection device according to an embodiment of the invention.

FIG. 12A shows an integrated circuit including the ESD protection device of FIG. 10A.

FIG. 12B shows an integrated circuit including the ESD protection device of FIG. 10B.

FIG. 12C shows an integrated circuit including the ESD protection device of FIG. 10C.

FIG. 13 shows an arrangement of an integrated circuit according to an embodiment of the invention.

FIG. 14 shows an arrangement of another integrated circuit according to an embodiment of the invention.

FIG. 15 shows a semiconductor chip having an ESD protection device according to an embodiment of the invention.

FIG. 16 shows a system according to an embodiment of the invention.

FIGS. 17-20 show various processes of a method of forming a transistor having textured surfaces according to various embodiments of the invention.

FIGS. 21-25 show various processes of a method of forming a transistor having textured surfaces according to other embodiments of the invention.

FIGS. 26-32 show various processes of a method of forming an ESD protection device having transistors with textured surfaces according to various embodiments of the invention.

FIGS. 33-40 show various processes of a method of forming another ESD protection device having transistors with textured surfaces according to other embodiments of the invention.

### DESCRIPTION OF EMBODIMENTS

The following description and the drawings illustrate specific embodiments of the invention sufficiently to enable those skilled in the art to practice it. Other embodiments may incorporate structural, logical, electrical, process, and other changes. In the drawings, like numerals describe substantially similar components throughout the several views. Examples merely typify possible variations. Portions and features of some embodiments may be included in or substituted for those of others. The scope of the invention encompasses the full ambit of the claims and all available equivalents.

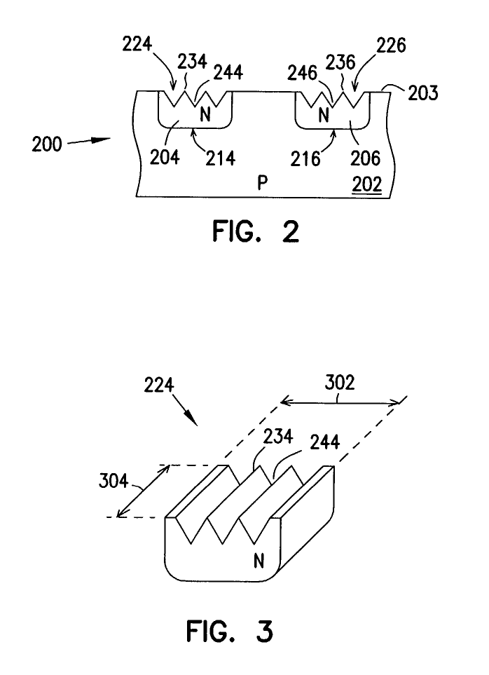

FIG. 2 is a cross-section of a bipolar transistor having a textured surface according to an embodiment of the invention. Transistor 200 includes a substrate 202 and doped regions 204 and 206 formed in the substrate. Substrate 202, doped regions 204 and 206 include semiconductor material, for example, silicon. Substrate 202 is doped with one kind of dopant (or impurity) to make it a first conductivity type material. Doped regions 204 and 206 are doped with another kind of dopant to make them a second conductivity type material. In some embodiments, doped regions 204 and 206 have a higher doping concentration than substrate 202 does.

In embodiments represented by FIG. 2, substrate 202 includes silicon doped with a dopant, for example boron, to make it a P-type material. Doped regions 204 and 206 include silicon doped with a dopant, for example phosphorous, to make them an N-type material. In some embodiments, substrate 202 can be an N-type material and doped regions 204 and 206 can be P-type material.

The N-type material (dopant) has excess electrons as majority carriers for conducting current. The P-type material (dopant) has excess holes as majority carriers for conducting current. In the description, the term “doped region” refers to a region having a semiconductor material doped with a dopant to become either an N-type material or a P-type material.

Substrate 202 has a surface 203. Doped regions 204 has a first surface 214 and a second surface 224. Surface 214 is surrounded by substrate 202 such that it is in contact with (or interfacing) substrate 202. Surface 224 is parallel (or co-planar) with surface 203 and is exposed on surface 203. In some embodiments, surface 224 is exposed but below surface 203. Doped region 206 has a first surface 216 and a second surface 226. Surface 216 is surrounded by substrate 202 such that it is in contact with (or interfacing) substrate 202. Surface 226 is parallel (or co-planar) with surface 203 and is exposed on surface 203. In some embodiments, surface 226 is exposed but below surface 203.

Each of the surfaces 224 and 226 is a textured surface. FIG. 2 shows one example of surfaces 224 and 226 being textured with a plurality of peaks 234, 236 and valleys 244 and 246. FIGS. 5-9 (described below) show other examples of textured surfaces which can replace surfaces 224 and 226 of FIG. 2. For simplicity, FIG. 2 only shows a cross-section of surfaces 224 and 226.

FIG. 3 is an isometric view of doped region 204 of FIG. 2. As shown in FIG. 3, surface 224 is textured such that its textured surface area is greater than its linear surface area. Surface 224 is bordered by linear dimensions 302 (length) and 304 (width). The linear surface area is the product of linear dimensions 302 and 304. In some embodiments, surface 224 can be bordered by a circle, oval or other shapes and the linear surface areas are defined by these shapes.

Transistor 200 of FIG. 2 can be used as a bipolar transistor. In FIG. 2, since substrate 202 has a P-type material and doped regions 204 and 206 have an N-type material, transistor 200 can be used as an NPN transistor with substrate 202 being the base and doped regions 204 and 206 being the emitter and collector. In some embodiments, when substrate 202 has an N-type material and doped regions 204 and 206 have a P-type material, transistor 200 can be used as a PNP transistor.

Since transistor 200 has textured surfaces, for equal emitter and collector surface areas, transistor 200 has a smaller size than that of a transistor without the textured surfaces. For example, in FIG. 3, without the textured surface, linear dimension 302 or 304 would have been longer to obtain the same surface area. In embodiments represented by FIG. 3, when transistor 200 and another transistor have equal emitter and collector surface areas and equal linear dimension 304, linear dimension 302 of transistor 200 is about 30 percent smaller than that of the other transistor without the textured surface. Thus, with textured surface areas, transistor 200 has a reduced size.

Conductive material can be formed on each of the doped regions 204 and 206 to provide electrical connection to these doped regions. Since doped regions 204 and 206 have textured surfaces, the conductive material conforms to the textured surface, creating a conductive material-doped region surface interface with textured surface. Since the surface interface is textured, it allows more current to pass through than a typical surface interface does.

In embodiments represented by FIG. 2, since transistor 200 has textured surfaces, it can be made with a size smaller than a typical transistor size but still maintain sufficient surface to provide adequate current and heat dissipation when it is used as an ESD protection device. In some embodiments, transistor 200 can have a typical transistor size but with textured surfaces. In these embodiments, transistor 200 can be used in non-ESD applications, such as high-current drivers.

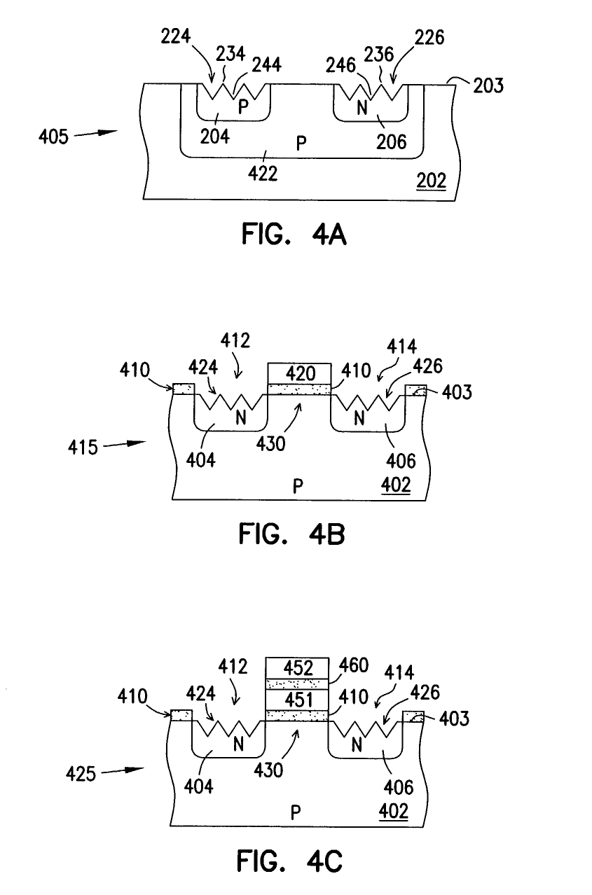

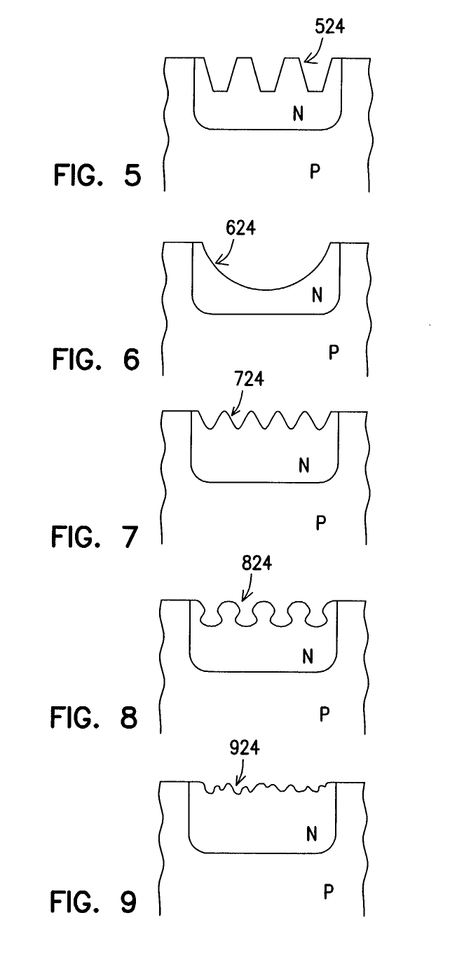

FIG. 4A is a cross-section of a diode having a textured surface according to an embodiment of the invention. Diode 405 has elements similar to the elements of transistor 200 (FIG. 2). In FIG. 4A, doped regions 204 and 206 are formed in a well 422 and have different conductivity types. For example, doped region 204 is a P-type and doped region 206 is an N-type. Well 422 is a P-type. In some embodiments, well 422 can be N-type, doped region 204 can be N-type, and doped region 206 can be P-type. In some other embodiments, well 422 can be omitted. Diode 405 has benefits similar to that of transistor 200 (FIG. 2).

FIG. 4B is a cross-section of a gated transistor having a textured surface according to another embodiment of the invention. Transistor 415 has a substrate 402 and doped regions 404 and 406 formed substrate 042. In some embodiments, doped regions 404 and 406 have a higher doping concentration than substrate 402 does. Doped regions 404 and 406 have surfaces 424 and 426. Surface 424 and 426 can be below the surface of substrate 402. In FIG. 4, transistor 415 has a gate 420 formed on an insulation layer 410. Gate 420 opposes a channel region 430 between doped regions 404 and 406. Insulation layer 410 is formed on a surface 403 of substrate 402. Insulation layer 410 has insulation openings 412 and 414 for exposing surfaces 424 and 426.

Surfaces 424 and 426 are textured surfaces. In embodiments represented by FIG. 4, surfaces 424 and 426 are textured in a similar manner as that of surfaces 224 and 226 (FIG. 2). In some embodiments, surfaces 424 and 426 can be textured in other manners including examples shown in FIGS. 5-9.

Transistor 415 can be used as a metal oxide field effect transistor (MOSFET). In FIG. 4, since substrate 402 has a P-type material and doped regions 404 and 406 have an N-type material, transistor 415 can be used as an n-channel transistor (NMOS transistor) with doped regions 204 and 206 being the source and drain. In embodiments where substrate 202 has an N-type material and doped regions 404 and 406 have a P-type material, transistor 415 is a p-channel transistor (PMOS transistor).

Similarly to transistor 200 (FIG. 2), for equal drain and source surface areas, transistor 415 has a smaller size than that of a transistor without textured surfaces.

Conductive material can be formed on each of the doped regions 404 and 406 to provide electrical connection to these doped regions. Since doped regions 404 and 406 have textured surfaces, the conductive material conforms to the textured surface, creating a conductive material-doped region surface interface with textured surface. Since the surface interface is textured, it allows more current to pass through than a typical surface interface does.

In embodiments represented by FIG. 4, since transistor 415 has textured surfaces, it can be made with a size smaller than a typical transistor size but still maintain sufficient surface to provide adequate current and heat dissipation when it is used as an ESD protection device. In some embodiments, transistor 415 can have a typical transistor size but with textured surfaces. In these embodiments, transistor 415 can be used in non-ESD applications, such as high-current drivers.

FIG. 4C is a cross-section of a floating gate transistor having a textured surface according to another embodiment of the invention. Transistor 425 has elements similar to the elements of transistor 404 (FIG. 4B). In FIG. 4C, transistor 425 has two gates: a floating gate 451 and a control gate 452. A second insulator layer 460 separates the gates. Transistor 425 can be used as a memory element to store data, in which the amount of charge in floating gate 420 corresponds to the value of the data. Transistor 425 has benefits similar to that of transistor 415 (FIG. 4B).

FIGS. 5-9 show examples of textured surfaces within transistors according to various embodiments of the invention. In FIGS. 5-9, the regions indicated by “P” correspond to substrate 202 and 402 of transistors 200 and 415 (FIGS. 2 and 4). The regions indicated by “N” correspond to doped regions 204, 206, 404, and 406 of transistors 200 and 415. Any of these surfaces can be used in any embodiment of the inventions.

In FIG. 5, surface 524 is textured such that it has a tooth-like shape with a plurality of sub-surfaces facing in different angles and in different planes. In FIG. 6, surface 624 is textured such that it has a curve shape with the curve being concave into the N region. In FIG. 7, surface 724 is textured such that it has one form of a wave shape. In FIG. 8, surface 824 is textured such that it has another form of a wave shape. In FIG. 9, surface 924 is textured such that it has a rough surface of irregular shape without a repeated pattern. Surfaces 524, 624, 724, 824, and 924 of FIGS. 5-9 are some examples of textured surfaces which can be used for each of the surfaces 224 and 226 (FIG. 2), and 424, and 426 (FIG. 4). The textured surfaces of FIGS. 2, and 5-9 can be patterned in a dimension similar to that of surface 224 of FIG. 3, or the textured surfaces in these Figures can be patterned in multiple dimensions.

Each of the textured surfaces in FIGS. 5-9 when applied to a transistor of any embodiment of the invention reduces the linear dimension of the transistor. For example, when surface 524 is applied to a diode or a transistor, the linear dimension of the diode or the transistor, such as linear dimension 302 (FIG. 3), is reduced by at least 70 percent while its surface area remains substantially equal to that of the linear surface (surface before texturing).

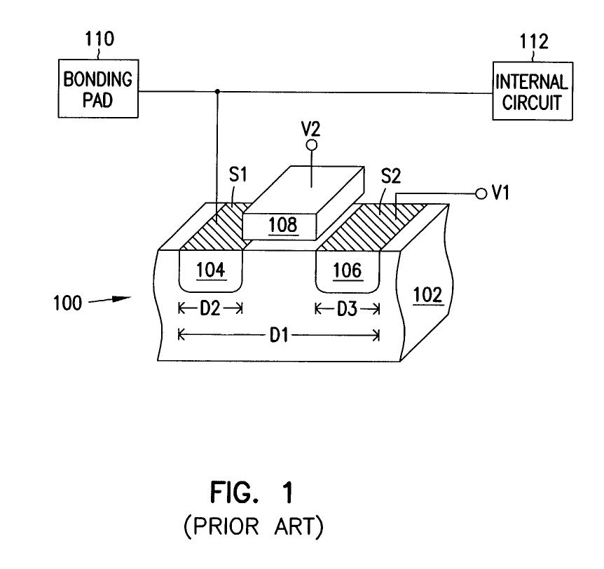

FIGS. 2, and 5-9 only show some examples of textured surfaces. In the description, the term “textured surface” is not limited to the textured surfaces shown in these figures. A textured surface in the description refers to any surface that is not flat such as that of surfaces S1 and S2 of FIG. 1. Further, the term textured surface in the description also refers to any surface having a surface area that is greater than the linear surface area calculated by the linear dimensions bordered the textured surface. Linear surface area and linear dimensions bordered the textured surface are described in FIG. 3. Moreover, the textured surface described in this description is not a microscopic rough surface resulted from imperfect process or from an unintentional task. The textured surface described in this description is intentionally created to reduce the linear dimension while increasing linear surface area.

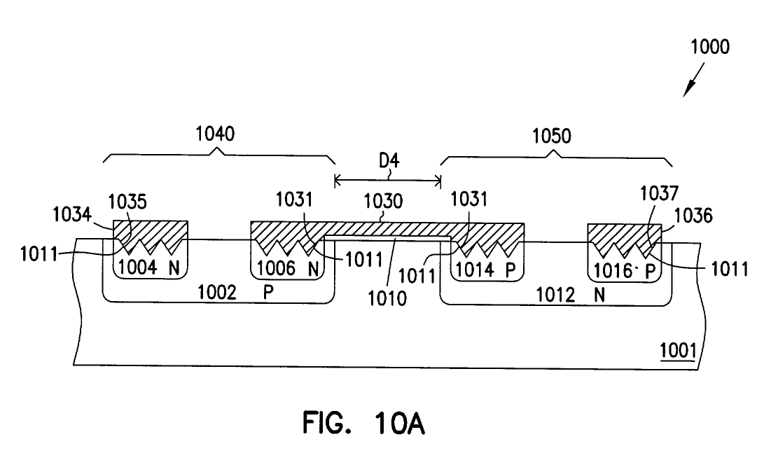

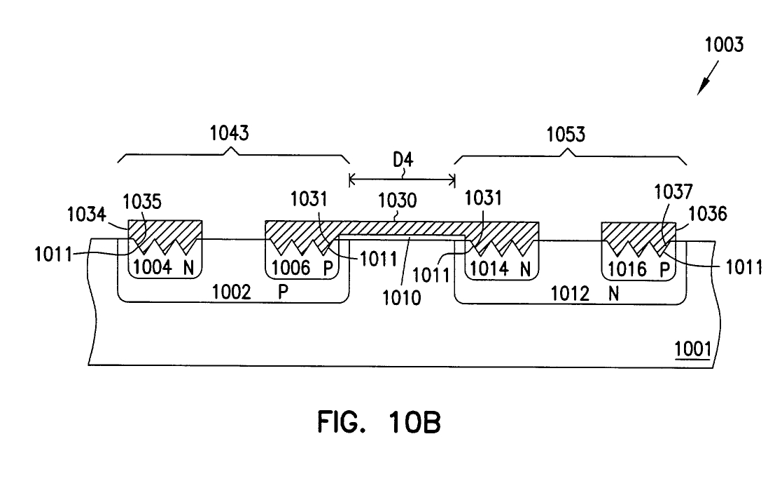

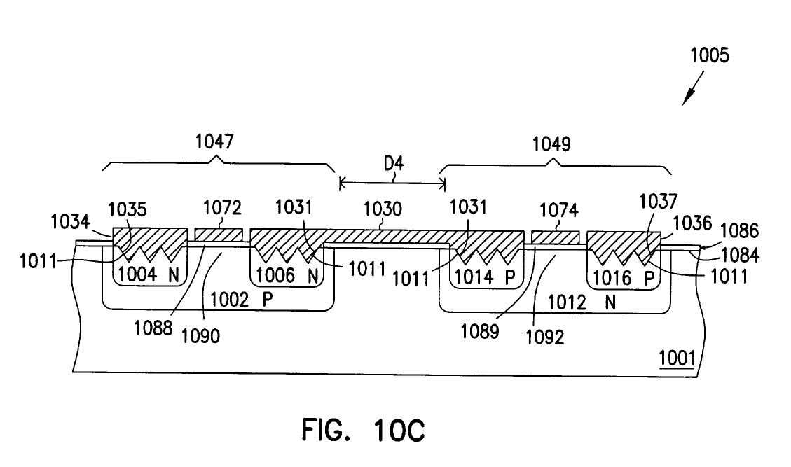

FIG. 10A is a cross-section of an ESD protection device having transistors with textured surfaces according to an embodiment of the invention. Device 1000 has a substrate 1001, first and second wells 1002 and 1012, first and second doped regions 1004 and 1006 formed in well 1002, and third and fourth doped regions 1014 and 1016 formed in well 1012. A bonding contact 1030 is formed and is separated from substrate 1001 by insulation layer 1010 on substrate 1001. Bonding contact 1030 has textured surfaces 1031 conforming to surfaces 1011 of doped regions 1006 and 1014 and connecting these two doped regions together. A supply contact 1034 is formed on doped region 1004. Supply contact 1034 has a textured surface 1035 conforming to surface 1011 of doped region 1004. Another supply contact 1036 is formed on doped region 1016. Supply contact 1036 has a textured surface 1037 conforming to surface 1011 of doped region 1016. Device 1000 has a linear dimension D4, which is also a linear dimension of a portion of bonding contact 1030.

Substrate 1001 can be either P-type or N-type material. Well 1002 is a doped region of P-type material and well 1012 is a doped region of N-type material. Doped regions 1004 and 1006 are N-type material and doped regions 1016 and 1016 are P-type material. Bonding contact 1030 and supply contacts 1034 and 1036 are made of conductive material.

Well 1002 and doped regions 1004 and 1006 form a first bipolar transistor 1040, in which doped regions 1004 and 1006 correspond to an emitter and a collector of the transistor and well 1002 corresponds to a base of the transistor. Well 1012 and doped regions 1014 and 1016 form a second bipolar transistor 1050, in which doped regions 1014 and 1016 correspond to an emitter and a collector of the transistor and well 1012 corresponds to a base of the transistor. Surface 1011 of each of the doped regions 1004, 1006, 1014, and 1016 is a textured surface. In embodiments represented by FIG. 10, surfaces 1011 is textured in a similar manner as that of surfaces 224 and 226 of transistor 200 (FIG. 2). In some embodiments, surfaces 1011 are textured such as that of surfaces 524, 624, 724, 824, and 924 (FIGS. 5-9).

FIG. 10B is a cross-section of an ESD protection device having reverse biased diodes with textured surfaces according to an embodiment of the invention. Device 1003 includes elements similar to elements of device 1000 (FIG. 10A). In FIG. 10B, doped regions 1004 and 1006 have different conductivity types. For example, doped regions 1004 is N-type and doped region 1006 is P-type. Doped regions 1014 and 1016 also have different conductivity types. For example, doped regions 1014 is N-type and doped region 1016 is P-type.

Well 1002 and doped regions 1004 and 1006 form a first diode 1043, in which doped regions 1004 and 1006 correspond to the cathode and anode of the diode. Well 1012 and doped regions 1014 and 1016 form a second diode 1053, in which doped regions 1014 and 1016 correspond to the anode and cathode of the diode. Doped regions 1004, 1006, 1014, and 1016 of diodes 1043 and 1053 have textured surface such as that of the texture surface of device 1000 (FIG. 10A).

FIG. 10C is a cross-section of an ESD protection device having transistors with textured surfaces according to another embodiment of the invention. Device 1005 includes elements similar to elements of device 1000 (FIG. 10A) and device 1003 (FIG. 10B). In FIG. 10C, device 1005 has gates 1072 and 1074 formed on an insulation layer 1086, which is formed on a surface 1084 of substrate 1001. Gate 1072 is separated from substrate 1001 by a portion 1088 of insulation layer 1086. Gate 1072 opposes a channel region 1090 between doped regions 1004 and 1006. Gate 1074 is separated from substrate 1001 by a portion 1089 of insulation layer 1086. Gate 1074 opposes a channel region 1092 between doped regions 1014 and 1016. Gate 1072, doped regions 1004 and 1006, channel region 1090, and well 1002 form a field effect transistor (FET) 1047, in which doped regions 1004 and 1006 correspond to a source and a drain of the transistor. Gate 1074, doped regions 1014 and 1016, channel region 1092, and well 1012 form another field effect transistor 1049, in which doped regions 1014 and 1016 correspond to a source and a drain of the transistor.

Since devices 1000, 1003, and 1005 (FIGS. 10A-C) include diodes and transistors having textured surfaces, D4 of devices 1000, 1003, and 1005 is smaller than that of a device having diodes or transistors without the textured surfaces, while providing adequate protection in case of and ESD event. For example, with textured surfaces 1011, D4 of devices 1000, 1003, and 1005 is about 30 percent smaller than that of a device having diodes or transistors without textured surfaces, such as transistor 100 of FIG. 1. As another example, when the diodes and transistors of devices 1000, 1003, and 1005 have textured surfaces such as texture surface 524 of FIG. 5, D4 of devices 1000, 1003, and 1005 is at least 70 percent smaller than that of a device having diodes or transistors without textured surfaces, such as transistor 100 of FIG. 1.

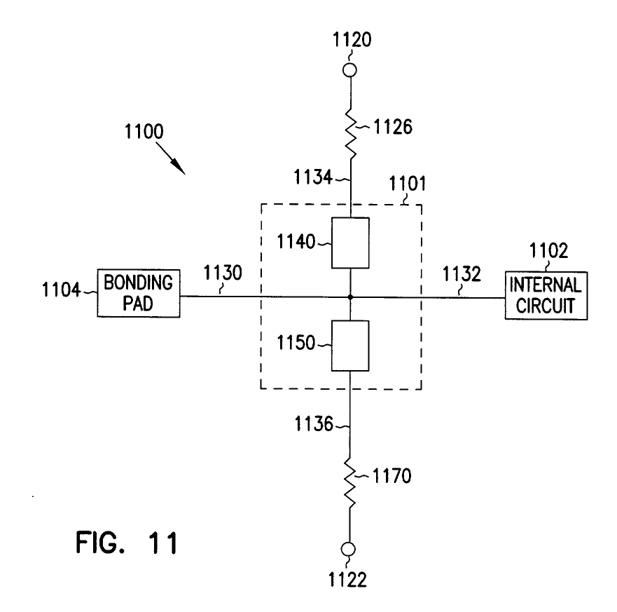

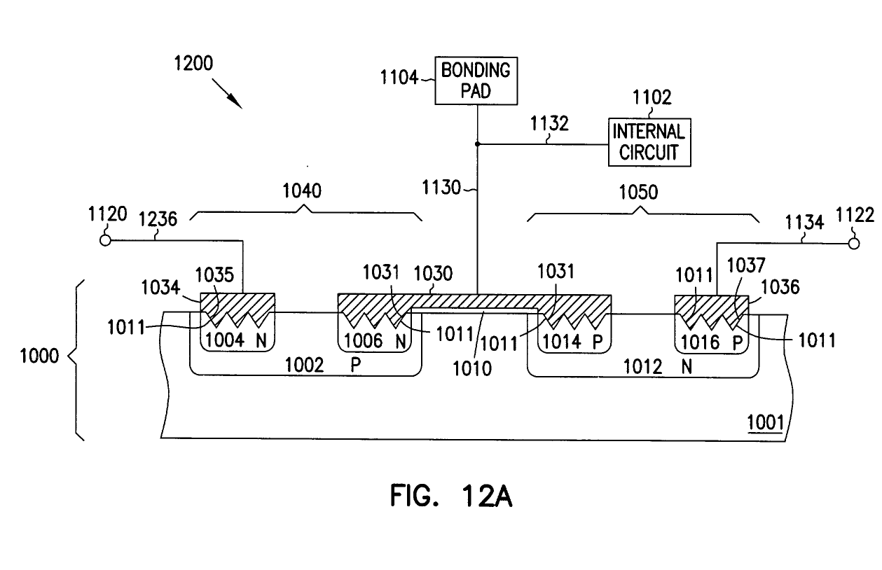

FIG. 11 shows an integrated circuit having an ESD protection device according an embodiment of the invention. Integrated circuit 1100 includes an internal circuit 1102 connected to a bonding pad 1104 at an internal node 1106. Device 1101 includes elements 1140 and 1150 connected to internal node 1106. Element 1140 further connects to a first supply node 1120 via line 1134 and a resistive element 1160. Element 1150 further connects to a second supply node 1122 via line 1136 and a resistive element 1170. Resistive elements 1160 and 1170 are shown as resistor symbols. These resistive elements, however, can be resistors, transistors operating as resistors, or other types of elements.

Device 1101 corresponds to device 1000 (FIG. 10), device 1003 (FIG. 10B), and device 1005 (FIG. 10C). Elements 1140 and 1150 correspond to transistors 1040 and 1050 (FIG. 10A), diodes 1043 and 1053 (FIG. 10B), and transistors 1047 and 1049 (FIG. 10C). In some embodiments, supply node 1120 has a voltage equal to the supply voltage of integrated circuit 1100 and supply node 1122 is ground. Bonding pad 1104 connects to internal node 1106 via connector 1130. Internal circuit 1102 connects to internal node 1106 via line 1132.

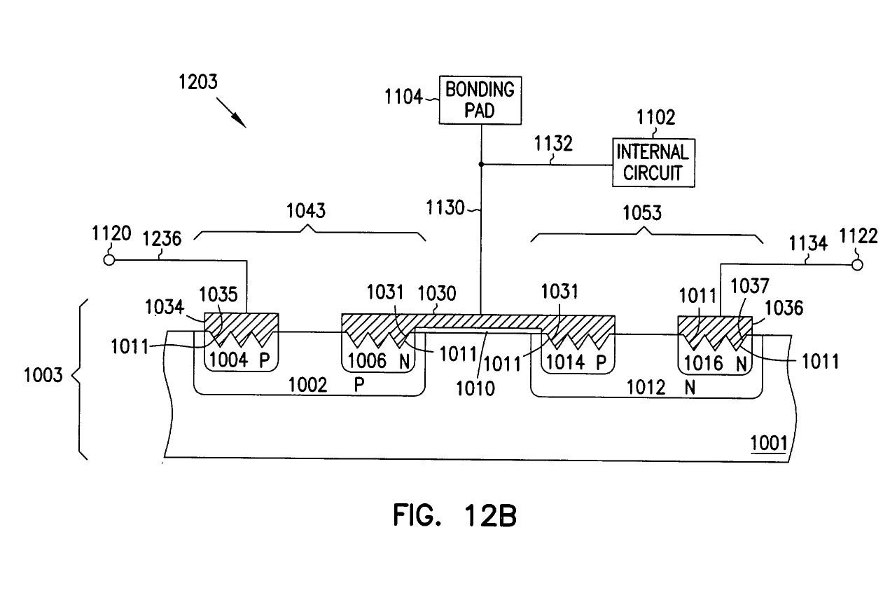

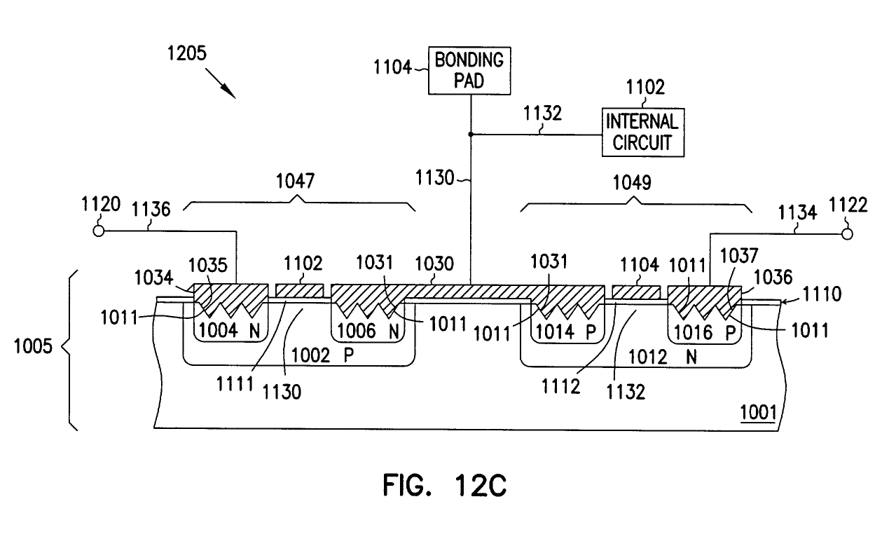

FIG. 12A shows an integrated circuit including the ESD protection device of FIG. 10A. Integrated circuit 1200 corresponds to integrated circuit 1100 of FIG. 11. In FIG. 12A, resistive elements 1160 and 1170 are omitted, and device 1000 corresponds to device 1101 of FIG. 11.

Referring to FIG. 12A, in a normal condition, the normal operating voltage at bonding pad 1104 is not high enough to cause current to flow in transistors 1040 and 1050. During an ESD event, when high ESD voltage having a positive polarity is applied to bonding pad 1104, an avalanche breakdown occurs at the p-n junction of doped region 1006 and well 1002. Current created by the ESD voltage begins to flow from doped region 1006 to well 1002 and causes the voltage of well 1002 to raise. The raised voltage in well 1002 causes the p-n junction between doped region 1004 and well 1002 to become conductive. Thus, doped regions 1004 and 1006 and well 1002 of transistor 1040 form a current path that allows current created by the ESD voltage to flow to node 1120 to protect internal circuit 1102. In the case when a negative polarity voltage is applied to bonding pad 1104 during an ESD event, transistor 1050 operates to allow the current created by the ESD voltage to flow to node 1122 to protect internal circuit 1102.

FIG. 12B shows an integrated circuit including the ESD protection device of FIG. 10B. Integrated circuit 1203 corresponds to integrated circuit 1100 of FIG. 11. In FIG. 12B, resistive elements 1160 and 1170 are omitted, and device 1003 corresponds to device 1101 (FIG. 11). The operation of integrated circuit 1203 is similar to the operation of integrated circuit 1200 of FIG. 12A.

FIG. 12C is an integrated circuit including the ESD protection device of FIG. 10C. Integrated circuit 1205 corresponds to integrated circuit 1100 of FIG. 11. In FIG. 12C, resistive elements 1160 and 1170 are omitted, and device 1005 corresponds to device 1101 of FIG. 11. The operation of integrated circuit 1205 of FIG. 12C is similar to the operation of integrated circuit 1200 of FIG. 12A.

In embodiments represented by FIGS. 12A-C, since devices 1000, 1003, and 1005 have diodes and transistors with textured surfaces, these transistors can be made with a size smaller than a typical diode size or a typical transistor size but still maintaining sufficient surface to provide adequate current and heat dissipation in an ESD events to protect the internal circuits. In some embodiments, the diodes and transistors of devices 1000, 1003, and 1005 can have a typical transistor size but with textured surfaces. In these embodiments, devices 1000, 1003, and 1005 can be used in non-ESD applications, such as high-current drivers.

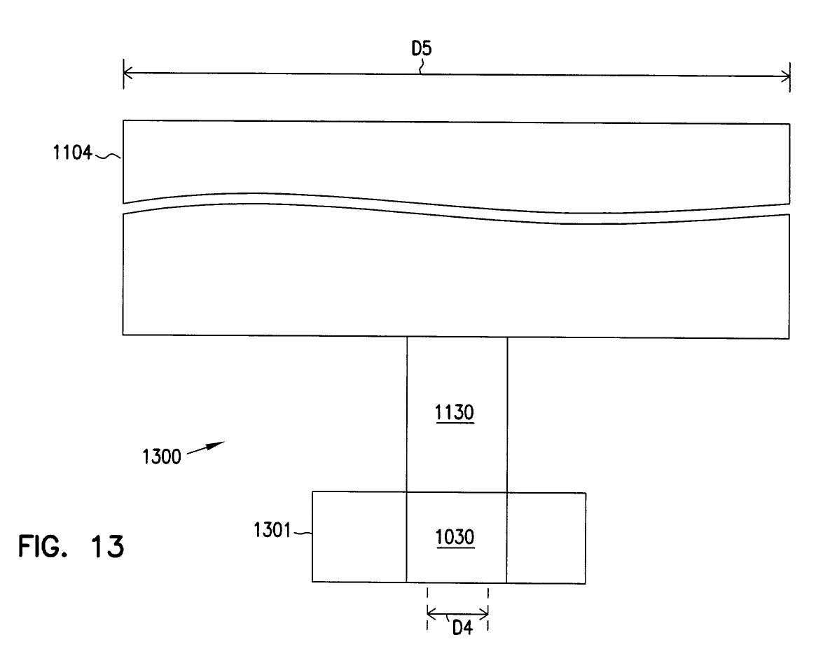

FIG. 13 shows a top view of an arrangement of an integrated circuit 1300 according to an embodiment of the invention. Integrated circuits 1300 includes bonding pad 1104 and device 1301 placed side-by-side and are connected together by connector 1130. Integrated circuit 1300 corresponds to integrated circuit 1200, 1203, or 1205 (FIGS. 12A-C) and device 1301 corresponds device 1000, 1003, or 1005 (FIGS. 10A-C). The elements in FIG. 13 are not scaled. Bonding pad 1104 has a linear dimension D5. Device 1301 has a linear dimension D4, which is similar to that of devices 1000, 1003, 1005 (FIGS. 10A-C).

As described in FIGS. 10A-C, D4 of device 1301 is smaller than that of a device without the textured surfaces, while providing adequate protection in case of and ESD event. Smaller D4 reduces the size of device 1000 and thus creating more room for other components in the integrated circuit, or reducing the overall size of the integrated circuit. Since device 1000 have texture surfaces, D5 of bonding pad 1104 can be made smaller than that of a bonding pad connected to a device without text surfaces. Smaller D5 also reduces the size of the bonding pad and thus creating more room for other components in the integrated circuit, or reducing the overall size of the integrated circuit.

FIG. 14 shows a side view of an arrangement of another integrated circuits 1400 according to an embodiment of the invention. Integrated circuits 1300 includes bonding pad 1104 and device 1401 placed in different circuit levels. For example, bonding pad 1104 is placed on top of device 1401. Connector 1130 includes one or more conducting lines 1444 connecting bonding pad 1104 and device 1401 together. Each conducting line 1444 includes conductive material filled in a via 1402 formed between the different circuit levels integrated circuit 1400. Integrated circuit 1400 corresponds to integrated circuit 1200, 1203, or 1205 (FIGS. 12A-C) and device 1401 corresponds device 1000, 1003, or 1005 (FIGS. 10A-C). The elements in FIG. 14 are not scaled. Bonding pad 1104 has a linear dimension D5. Device 1401 has a linear dimension D4, which is similar to that of devices 1000, 1003, 1005 (FIGS. 10A-C). Similarly to integrated circuit 1300 of FIG. 13, dimensions D4 and D5 of bonding pad 1104 and device 1000 of integrated circuit 1400 FIG. 14 are also smaller than that of a bonding pad connected to a device without the texture surfaces. This creates more room for other components in the integrated circuit, or reduces the overall size of the integrated circuit.

FIG. 15 shows a semiconductor chip having an ESD protection device according to an embodiment of the invention. Chip 1500 includes a package 1502 enclosing an integrated circuit 1504. Integrated circuit 1504 can be a processor, controller, memory device, application specific integrated circuit, or other type of integrated circuit. Chip 1500 also includes a plurality of external contacts 1506 connected to integrated circuit 1504 via a plurality of bonding pads 1508. In embodiments represented by FIG. 15, external contacts 1506 are external pins. In some embodiments, external contacts have other shapes, such as ball contacts.

Integrated circuit 1504 includes an internal circuit 1530 connected to one of the bonding pads 1508 at an internal node 1510. An ESD protection device 1512 includes elements 1540 and 1550 connected to internal node 1510 to discharge an ESD current from one of the external contacts 1506 to supply nodes 1520 or 1522 during an ESD event. A first resistive element R1 connects between elements 1540 and supply node 1520. A second resistive element R2 connects between elements 1550 and supply node 1522. In some embodiments, supply node 1520 connects to the supply voltage of integrated circuit 1504 and supply node1522 connects to ground.

Integrated circuit 1504 corresponds to integrated circuit 1200, 1203, and 1205 (FIG. 12A-C). Device 1512 have similar structure as that of devices 1000, 1003, and 1005 (FIGS. 12A-C) including diodes and transistors with textured surfaces. Elements 1540 and 1550 have similar structures and operate in a similar manner as that of transistors 1040 and 1050 (FIG. 12A), diodes 1043 and 1053 (FIG. 12B), and transistors1047 and 1049 (FIG. 12C).

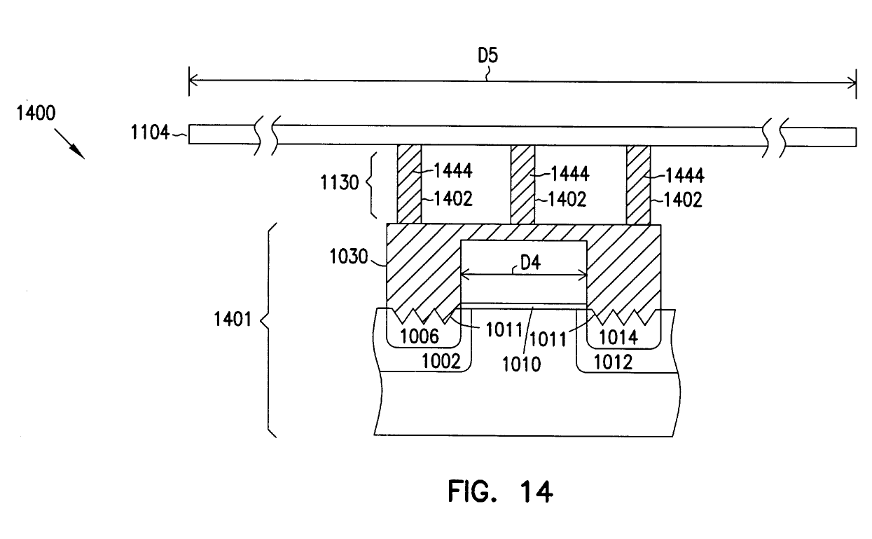

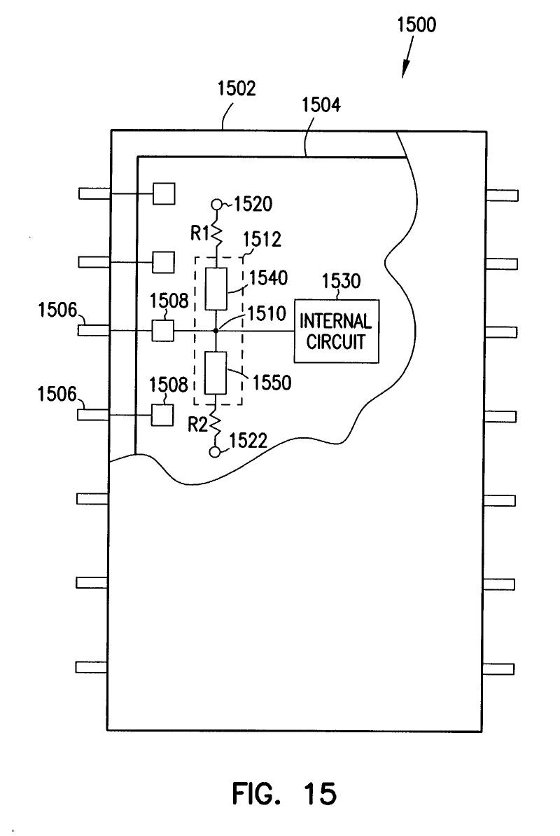

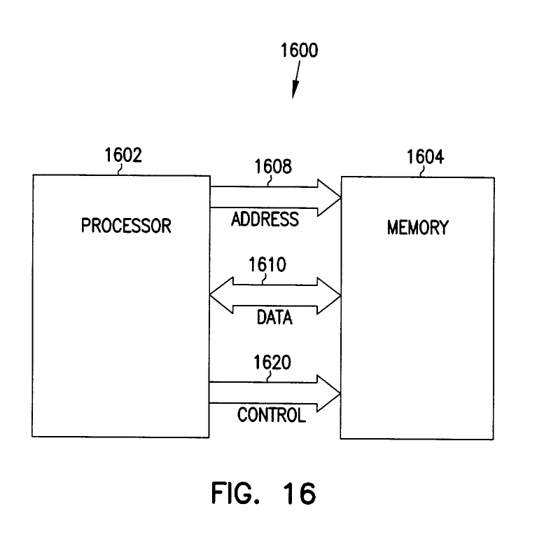

FIG. 16 shows a system according to an embodiment of the invention. System 1600 includes chips 1602 and 1604. These chips can be processors, controllers, memory devices, application specific integrated circuits, and other types of integrated circuits. In embodiments represented by FIG. 16, for example, chip 1602 represents a processor, and chip 1602 represents a memory device. Processor 1602 and memory device 1604 communicate using address signals on lines 1608, data signals on lines 1610, and control signals on lines 1620. In embodiments represented by FIG. 16, chips 1602 and 1604 are enclosed in different packages. In some embodiments, chips 1602 and 1604 can be enclosed in the same package.

Each of the chips 1602 and 1604 corresponds to chip 1500 (FIG. 15). Thus, each of the chips 1602 and 1604 includes elements similar to elements of chips 1500 including ESD protection devices having diodes and transistors with textured surfaces as described in this description.

System 1600 represented by FIG. 16 includes computers (e.g., desktops, laptops, hand-helds, servers, Web appliances, routers, etc.), wireless communication devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

FIGS. 17-20 show various processes of a method of forming a transistor having textured surfaces according to various embodiments of the invention. In FIG. 17, a mask 1703 is placed over a substrate 1702. Mask 1703 is patterned to have mask openings 1704 to expose portions of substrate 1702 at the mask openings. Dopant is introduced (arrows 1706) to substrate 1702 through mask openings 1704. In FIG. 18, emitter and collector regions 1804 and 1814 are formed after the dopant is introduced. Each of the emitter and collector region has an exposed surface 1711. In FIG. 19, the method textures surfaces 1711 of emitter and collector regions 1804 and 1814 to increase their surface areas. In some embodiments, texturing surfaces 1711 includes etching surfaces 1711 to change the shapes of these surfaces such that the surface areas after the texturing is greater than the surface areas before the texturing. In FIG. 20, after the texturing, surfaces 1711 are now textured surfaces 2011. As shown in FIG. 20, textured surfaces 2011 are larger than surfaces 1711.

In some embodiments, the etching can be performed by standard photolithographic methods. A photo-resist layer is placed over the substrate and then patterned with the openings in the photo-resist-layer. The openings match the locations of the textured features. The silicon in the substrate at the openings is etched to have the pattern of surface 2011 (FIG. 20). The patterned photo-resist layer is removed after etching. Surface 2011 can also have patterns such as those of FIGS. 5-8.

In other embodiments, a negative resist could be applied or KOH (potassium Hydroxide) could be used to form the textured surface. In some other embodiments, the texturing includes the use of a mask such as a Nitride hard mask patterned with openings in it. A subsequent Selective Epitaxi Growth (SEG) process can be performed to produce the textured surface.

In some embodiments, a single doped region having a textured surface can be formed using a method similar to the method described in FIGS. 17-20. In these embodiments, the single doped region with the textured surface serves as node or as a contact for contacting (or interfacing) with another node or another contact (or layer) in an integrated circuit.

The processes described in FIGS. 17-20 can be used to make transistor 200 (FIG. 2). The processes described in FIGS. 17-20 can also be used to make diode 405 (FIG. 4A). In FIG. 17, to make diode 405, dopants of different types can be introduced into substrate 1702 at openings 1704 to make regions 1804 and 1814 (FIG. 18) to have different conductivity types. For example, P-type dopant can be introduced into one opening 1704 and N-type dopant can be introduced into the other opening 1704 to make region 1804 a P-type and region 1814 an N-type. This is similar to the different types of doped regions 204 and 206 of diode 405 (FIG. 4A). In some embodiments, a well can be formed in FIG. 17 before regions 1804 and 1814 are formed in FIG. 18.

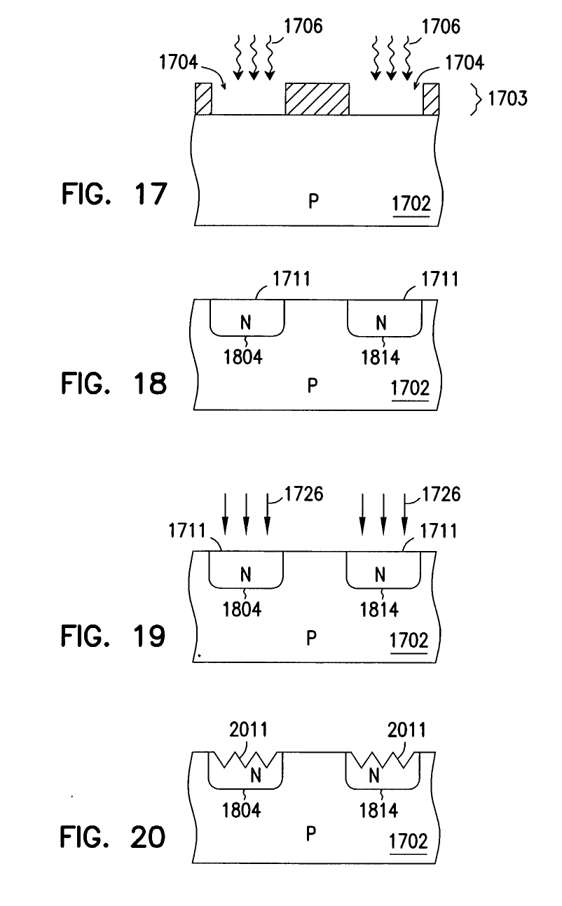

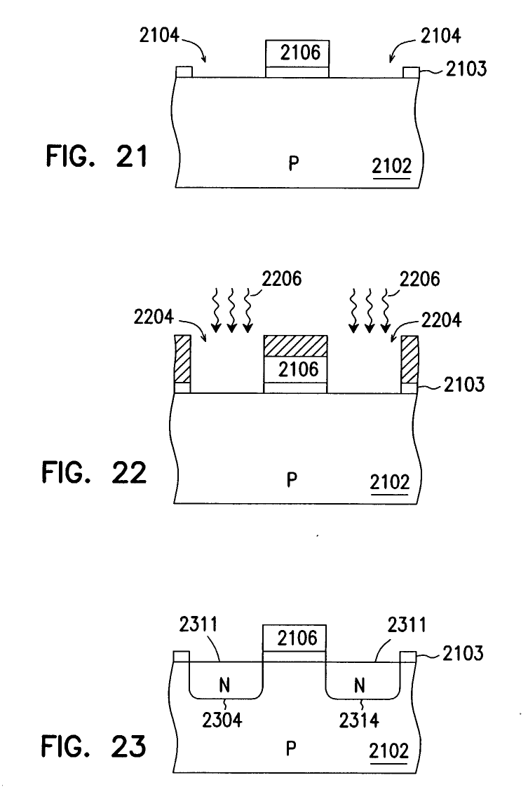

FIGS. 21-25 show various processes of a method of forming a transistor having textured surfaces according to other embodiments of the invention. In FIG. 21, a gate 2106 is formed on a substrate 2102 and is separated by a portion of an insulation layer 2103, which is formed on the substrate. In FIG. 22, a mask 2203 is placed over gate 2106 and exposed portions of insulation layer 2103. Mask 2203 is patterned to have mask openings 2204 to expose portions of substrate 2102 at the mask openings. Dopant is introduced (arrows 2206) to substrate 2102 through mask openings 2204. In FIG. 23, source and drain regions 2304 and 2314 are formed after the dopant is introduced. Each of the source and drain regions has an exposed surface 2311.

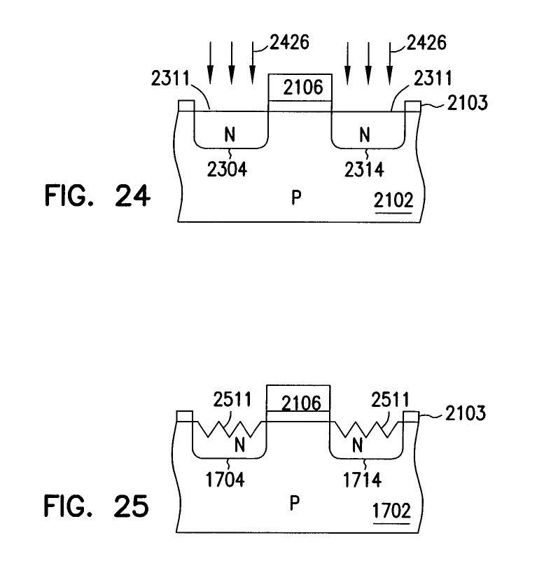

In FIG. 24, the method textures surfaces 2311 of source and drain regions 2304 and 2314 to increase their surface areas. In some embodiments, texturing surfaces 2311 includes etching surfaces 2311 to change the shapes of these surfaces such that the surface areas after the texturing is greater than the surface areas before the texturing. In FIG. 25, after the texturing, surfaces 2311 are now textured surfaces 2511. As shown in FIG. 25, textured surfaces 2511 are larger than surfaces 2411. Texturing surface 2311 can be performed by methods similar to the methods described in FIGS. 19-20.

The processes described in FIGS. 21-25 can be used to make transistor 415 (FIG. 4B). The processes described in FIGS. 21-25 can also be used to make transistor 425 (FIG. 4C). In FIG. 21, to make transistor 425, a second insulation layer is formed on gate 2106, and a control gate is formed on the second insulator layer. This is similar to second insulator layer 460 and control gate 452 of floating gate transistor 425 (FIG. 4C).

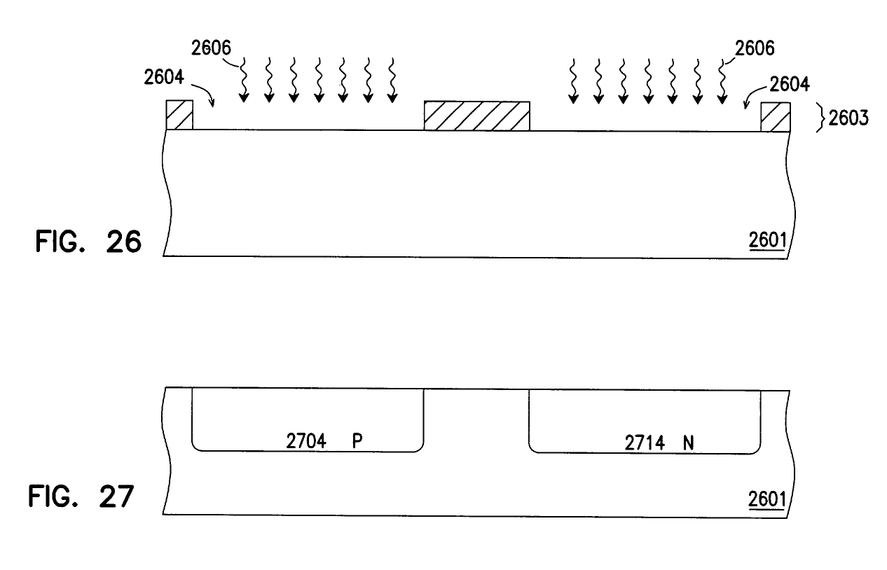

FIG. 26-32 show various processes of a method of forming an ESD protection device having transistors with textured surfaces according to various embodiments of the invention. In FIG. 26, a mask 2603 is placed over a substrate 2601. Mask 2603 is patterned to have mask openings 2604 to expose portions of substrate 2601 at the mask openings. Dopants of different conductivity types are introduced (arrows 2606) to substrate 2601 through mask openings 2604. In FIG. 27, wells 2704 and 2714 are formed after the dopants are introduced. Well 2704 is a doped region of P-type and well 2714 is a doped region of N-type. Wells 2704 and 2714 can be formed in separate doping process. For example, well 2704 can be formed first in one doping process and well 2714 can be formed second in another doping process.

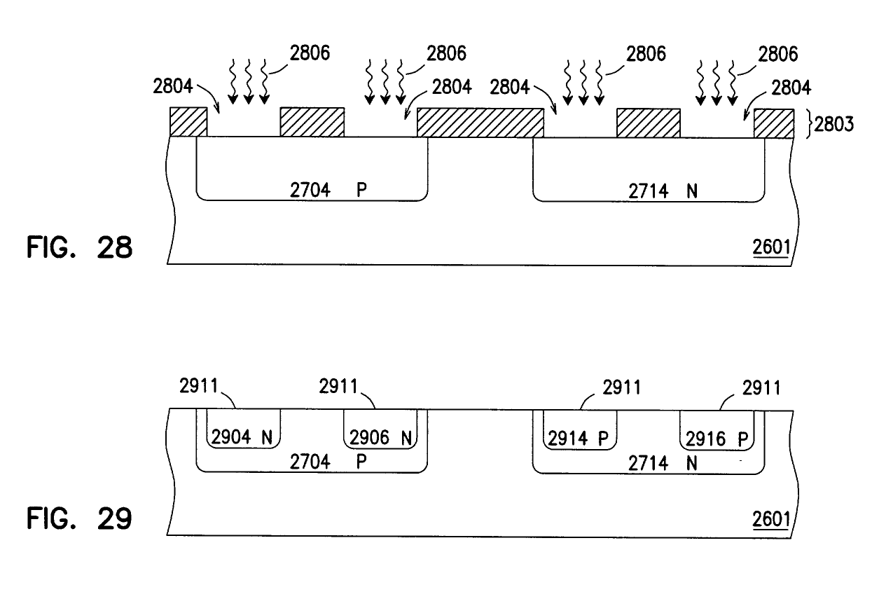

In FIG. 28, a mask 2803 is placed over a substrate 2601. Mask 2803 is patterned to have mask openings 2804 to expose portions of wells 2704 and 2714 at the mask openings. Dopants of different conductivity types are introduced (arrows 2806) to wells 2704 and 2714 through mask openings 2804. In FIG. 29, after the dopants are introduced, doped regions 2904 and 2906 are formed in well 2704 and doped regions 2914 and 2916 are formed in well 2714. Doped regions 2904 and 2906 have N-type material and doped regions 2914 and 2916 have P-type material. The pair of doped regions 2904 and 2906 and the pair of doped regions 2914 and 2916 can be formed in separate doping process. For example, doped regions 2904 and 2906 can be formed first in one doping process and doped regions 2914 and 2916 can be formed second in another doping process. Each of the doped regions has an exposed surface 2911.

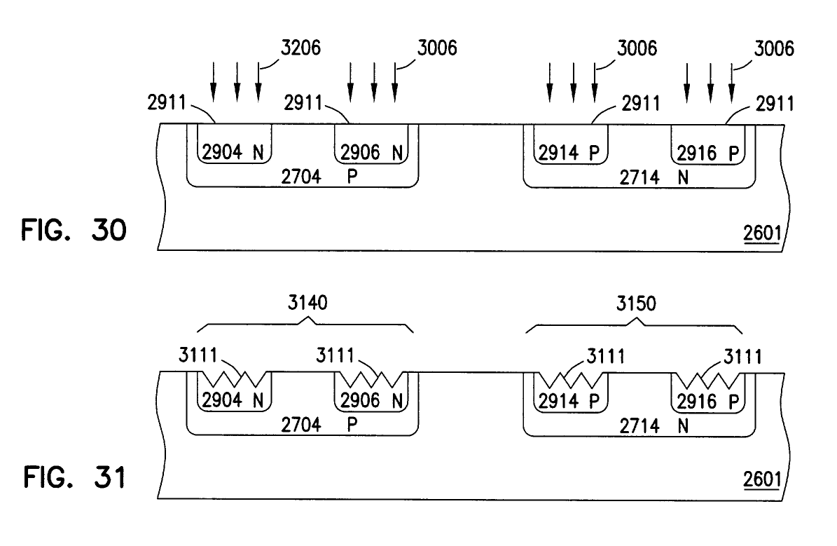

In FIG. 30, the method textures surfaces 2911 of each of the doped regions 2904, 2906, 2914, and 2916 to increase their surface areas. In some embodiments, texturing surfaces 2911 includes etching surfaces 2911 to change the shapes of these surfaces such that the surface areas after the texturing is greater than the surface areas before the texturing. Texturing surface 2911 can be performed by methods similar to the methods described in FIGS. 19-20.

In FIG. 31, after the texturing, surfaces 2911 are now textured surfaces 3111. As shown in FIG. 31, textured surfaces 3111 are larger than surfaces 2911. Well 2704, and doped regions 2904 and 2906 form a transistor 3140. Well 2714, and doped regions 2914 and 2916 form a transistor 3150.

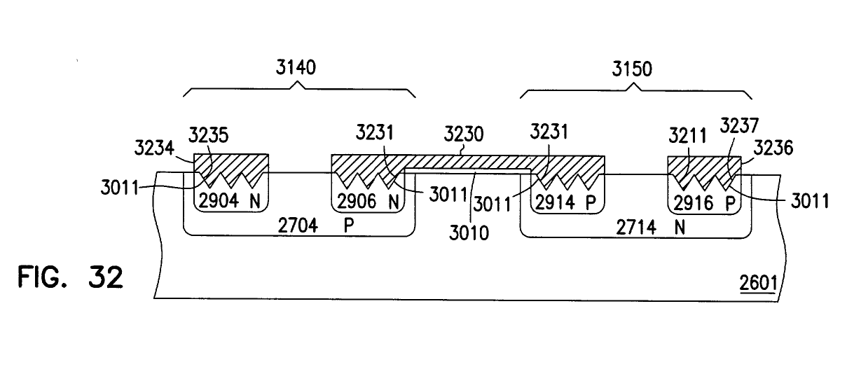

In FIG. 32, a bonding contact 3230, and supply contacts 3234 and 3236 are formed. Bonding contact 3230 is separated from substrate 2601 by insulation layer 3010 on substrate 1161. Bonding contact 3230 has textured surfaces 3231 conforming to surfaces 3011 of doped regions 2906 and 2914 and connecting these two doped regions together. Supply contact 1034 is formned on doped region 2904 and has a textured surface 3235 conforming to surface 3011 of doped region 2904. Supply contact 3236 is formed on doped region 2916 and a textured surface 3237 conforming to surface 3011 of doped region 2916. Each of surfaces 3231, 3235, and 3237 is a textured surface because it is formed on top of a textured surface of a corresponding doped region.

The processes described in FIGS. 26-32 can be used to make device 1000 (FIG. 10A). The processes described in FIGS. 26-32 can also be used to make device 1003 (FIG. 10B). In FIG. 28, to make device 1003, dopants of different types can be introduced into substrate 2601 at openings 2804 to make regions 2904 and 2906 to have different types and regions 2914 and 2916 to have different types. For example, P-type dopant can be introduced into two of the openings 2804 and N-type dopant can be introduced into the other two of the openings 2804 to make regions 2904 and 2914 (FIG. 29) an N-type and regions 2906 and 2916 a P-type. This is similar to the different types between doped regions 1004 and 1006 and between doped regions 1014 and 1016 of device 1003 (FIG. 10B).

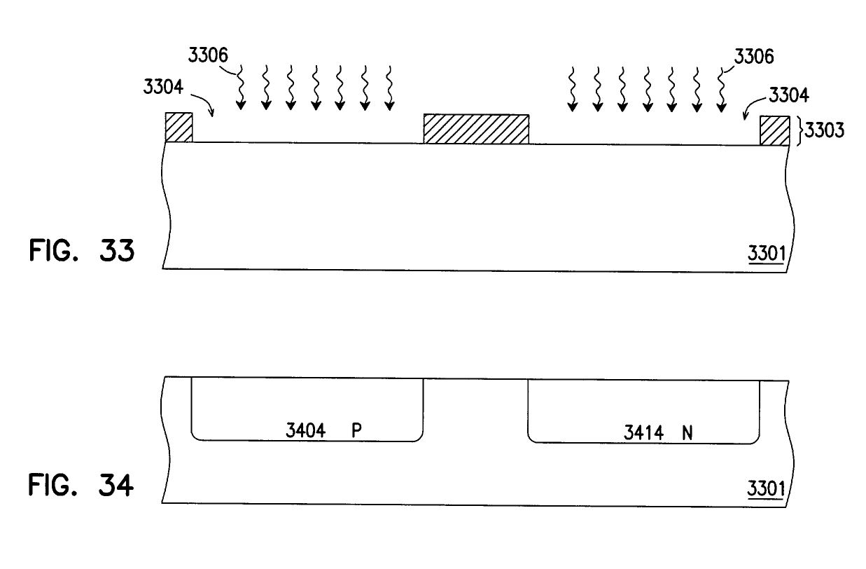

FIGS. 33-40 show various processes of a method of forming an ESD protection device having transistors with textured surfaces according to other embodiments of the invention. In FIG. 33, a mask 3303 is placed over a substrate 3301. Mask 3303 is patterned to have mask openings 3304 to expose portions of substrate 3301 at the mask openings. Dopants of different conductivity types are introduced (arrows 3306) to substrate 3301 through mask openings 3304. In FIG. 34, wells 3404 and 3414 are formed after the dopants are introduced. Well 3404 is a doped region of P-type and well 2714 is a doped region of N-type. Wells 3404 and 3414 can be formed in separate doping process. For example, well 3404 can be formed first in one doping process and well 3414 can be formed second in another doping process.

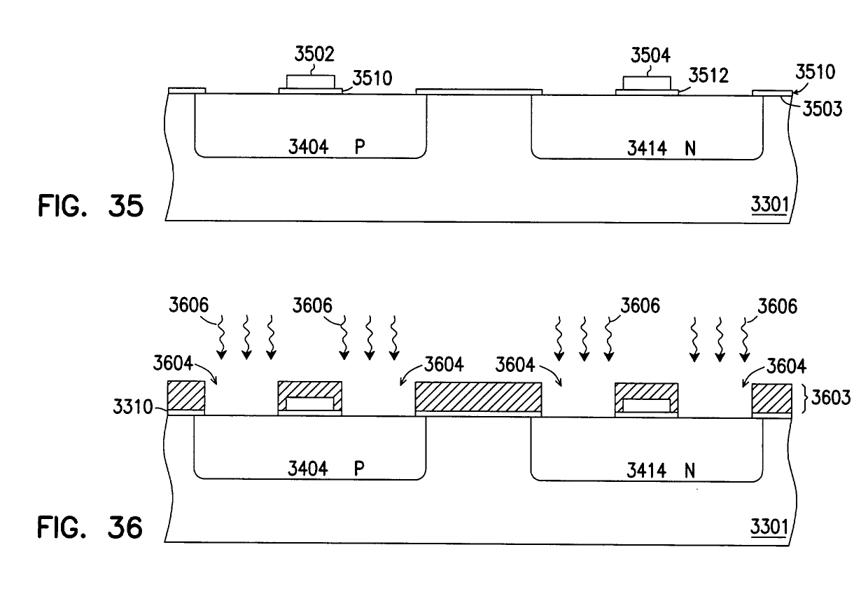

In FIG. 35, gates 3302 and 3304 are formed on an insulation layer 3110, which is formed on a surface 3503 of substrate 3301. Gate 3502 is separated from substrate 3301 by a portion 3511 of insulation layer 3510. Gate 3504 is separated from substrate 3301 by a portion 3512 of insulation layer 3510. In FIG. 36, a mask 3603 is placed over gates 3502 and 3504, and insulation layer 2103. Mask 3603 is patterned to have mask openings 3604 to expose portions of substrate 3301 at the mask openings. Dopants of different conductivity types are introduced (arrows 3606) to wells 3404 and 3414 through mask openings 2204.

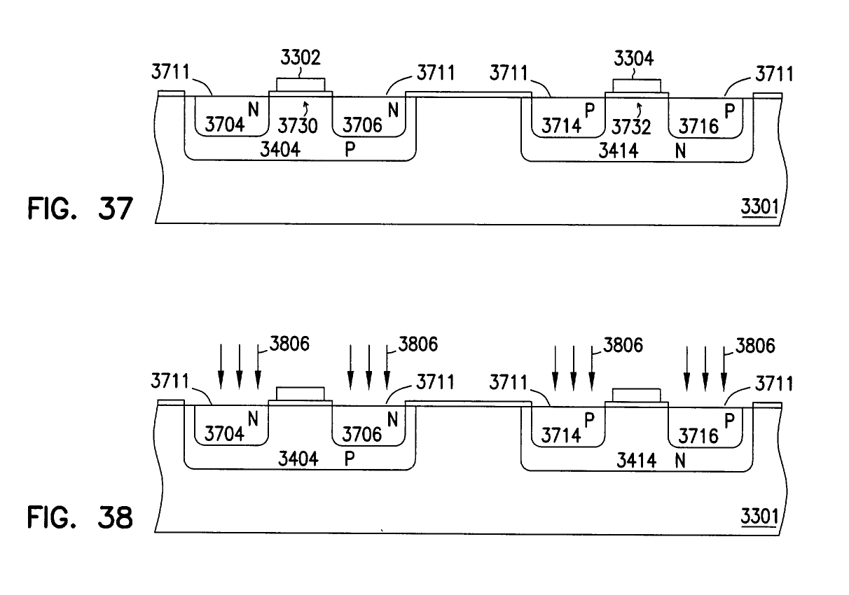

In FIG. 37, after the dopants are introduced, doped regions 3704 and 3706 are formed in well 3704 and doped regions 3714 and 3716 are formed in well 3714. Gate 3302 opposes a channel region 3730 between doped regions 3704 and 3706. Gate 3304 opposes a channel region 3732 between doped regions 3714 and 3766. Doped regions 3704 and 3706 have P-type material and doped regions 3714 and 3716 have N-type material. The pair of doped regions 3704 and 3706 and the pair of doped regions 3714 and 3716 can be formed in separate doping process. For example, doped regions 3704 and 3706 can be formed first in one doping process and doped regions 3714 and 3716 can be formed second in another doping process. Each of the doped regions has an exposed surface 3711.

In FIG. 38, the method textures surfaces 3711 of each of the doped regions 3704, 3706, 3714, and 3716 to increase their surface areas. In some embodiments, texturing surfaces 3711 includes etching surfaces 3711 to change the shapes of these surfaces such that the surface areas after the texturing is greater than the surface areas before the texturing. Texturing surface 3711 can be performed by methods similar to the methods described in FIGS. 19-20.

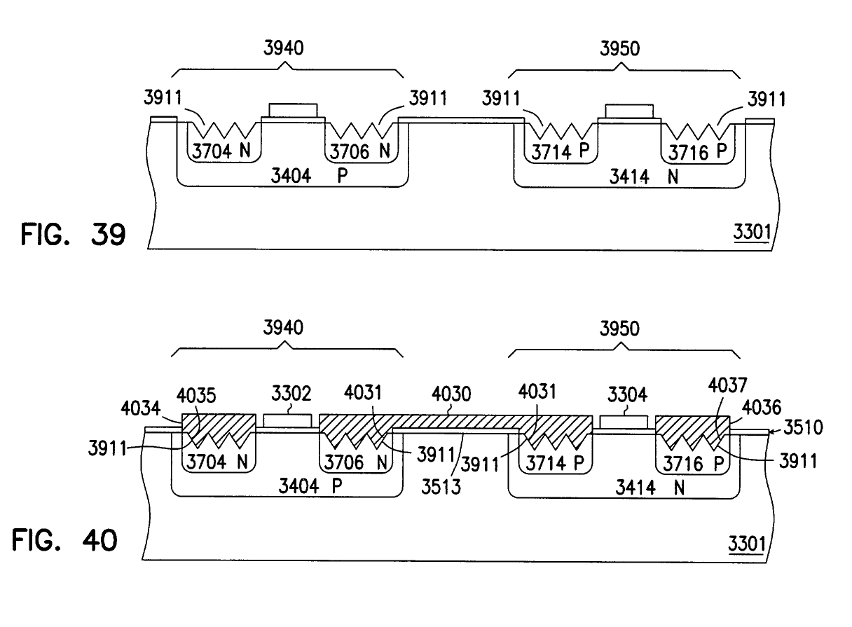

In FIG. 39, after the texturing, surfaces 3711 are now textured surfaces 3911. As shown in FIG. 31, textured surfaces 3911 are larger than surfaces 3711. Well 3704, and doped regions 3704 and 3706 form a transistor 3940. Well 3714, and doped regions 3714 and 3716 form a transistor 3950.

In FIG. 40, a bonding contact 4030, and supply contacts 4034 and 4036 are formed. Bonding contact 4030 is separated from substrate 3301 by portion 3513 of insulation layer 3510. Bonding contact 4030 has textured surfaces 4031 conforming to surfaces 3911 of doped regions 3706 and 3714 and connecting these two doped regions together. Supply contact 4034 is formed on doped region 3704 and has a textured surface 4035 conforming to surface 3911 of doped region 3704. Supply contact 4036 is formed on doped region 3716 and a textured surface 4037 conforming to surface 3911 of doped region 3716.

The processes described in FIGS. 33-40 can be used to make device 1005 (FIG. 10C).

### Conclusion

Various embodiments of the invention describe circuits and methods to reduce the size of transistors and diodes while maintaining adequate surface areas so that when these transistors and diodes are used as ESD protection devices, they provide sufficient protection. In some embodiments, these transistors can have a typical transistor size but with textured surfaces so that they can be used in non-ESD applications, such as high-current drivers. Although specific embodiments are described herein, those skilled in the art recognize that other embodiments may be substituted for the specific embodiments shown to achieve the same purpose. This application covers any adaptations or variations of the present invention. Therefore, the present invention is limited only by the claims and all available equivalents.

What is claimed is:

1. A device comprising:
a substrate;
a first doped region formed in the substrate; and
a second doped region formed in the substrate, wherein each of the first and second doped regions includes a textured surface.

2. The device of claim 1, wherein the textured surface is exposed on a surface of the substrate.

3. The device of claim 1, wherein the first and second doped regions are separated by a portion of the substrate.

4. The device of claim 1, wherein the substrate includes material of first conductivity type, and the first and second doped regions include material of second conductivity type.

5. The device of claim 1, wherein the substrate and the first doped region include material of first conductivity type, and second doped region includes material of second conductivity type.

6. The device of claim 5, wherein the each of first and second doped regions has a higher doping concentration than the substrate.

7. The device of claim 6, wherein one of the first and second conductivity types is a P-type and the other conductivity type is an N-type.

8. A device comprising:
a substrate;
an insulation layer formed on the substrate;
a first doped region formed in the substrate;
a second doped region formed in the substrate and separated from the first doped region by a channel region, wherein each of the first and second doped regions includes a textured surface; and
a first gate formed on the insulation layer separated from the substrate and opposing the channel region.

9. The device of claim 8, wherein the textured surface is exposed on a surface of the substrate.

10. The device of claim 8, wherein the substrate includes material of first conductivity type and the first and second doped regions include material of second conductivity type.

11. The device of claim 8 further comprising a second gate formed over the first gate.

12. The device of claim 11 further comprising a second insulation layer sandwiched between the first and second gates.

13. The device of claim 8, wherein one of the first and second conductivity types is a P-type and the other conductivity type is an N-type.

14. A device comprising:
a substrate; and
a doped region formed in the substrate, wherein the doped region includes a textured surface.

15. The device of claim 14, wherein the substrate includes material of first conductivity type and the first and second doped regions include material of second conductivity type.

16. The device of claim 14, wherein one of the first and second conductivity types is a P-type and the other conductivity type is an N-type.

17. A protection device comprising:
a first transistor having a first doped region, a second doped region formed in the first doped region, and a third doped region formed in the first doped region, wherein the second doped region includes a textured surface connected to a bonding contact, and the third doped regions includes a textured surface connected to a first supply contact; and
a second transistor having a first doped region, a second doped region formed in the first doped region, and a third doped region formed in the first doped region, wherein the second doped region includes a textured surface connected to the bonding contact, and the third doped region includes a textured surface connected to a second supply contact.

18. The protection device of claim 17, wherein the bonding contact includes:
a first textured surface conforming to the textured surface of the second doped region of the first transistor; and
a second textured surface conforming to the textured surface of the second doped region of the second transistor.

19. The protection device of claim 17, wherein the first supply contact includes a textured surface conforming to the textured surface of the third doped region of the first transistor.

20. The protection device of claim 17, wherein the second supply contact includes a textured surface conforming to the textured surface of the third doped region of the second transistor.

21. The protection device of claim 17, wherein the first doped region of first transistor includes material of first conductivity type and the first doped region of second transistor includes material of second conductivity type.

22. The protection device of claim 17, wherein the first doped region of first transistor includes material of first conductivity type and the second and third doped regions of the first transistor include material of second conductivity type.

23. The protection device of claim 22, wherein the first doped region of first transistor includes material of second conductivity type and the second and third doped regions of the second transistor include material of first conductivity type.

24. An integrated circuit comprising:
an internal circuit;
a bonding pad connected to the internal circuit; and
a protection device connected to the bonding pad, the protection device including:
a first transistor having a first doped region, a second doped region and a third doped region formed in the first doped region, the second doped region connecting to the bonding pad, the third doped regions connecting to a first supply node; and
a second transistor having a first doped region, a second doped region and a third doped region formed in the first doped region, the second doped region connecting to the bonding pad, the third doped region connected to a second supply node, wherein each of the second and third doped regions of the first and second transistors includes a textured surface.

25. The integrated circuit of claim 24, wherein the first doped region of first transistor includes material of first conductivity type and the first doped region of second transistor includes material of second conductivity type.

26. The integrated circuit of claim 24, wherein one of the first and second supply nodes has a positive voltage and the other supply node is ground.

27. The integrated circuit of claim 24 further comprising a resistor connected between the first transistor and the first supply node.

28. The integrated circuit of claim 24 further comprising a resistor connected between the second transistor and the second supply node.

29. The integrated circuit of claim 24 further comprising:
a first resistor connected between the first transistor and the first supply node; and
a second resistor connected between the second transistor and the second supply node.

30. A protection device comprising:
a substrate;
a first well and a second well formed in the substrate;
a first doped region and a second doped region formed in the first well, wherein the first doped region includes a textured surface connected to a first supply contact, and the second doped region includes a textured surface connected to a bonding contact; and
a third doped region and a fourth doped region formed in the second well, wherein the third doped region includes a textured surface connected to the bonding contact, and the fourth doped region includes a textured surface connected to a second supply contact.

31. The protection device of claim 30, wherein the bonding contact includes:
a first textured surface conforming to the textured surface of the second doped region; and
a second textured surface conforming to the textured surface of the third doped region.

32. The protection device of claim 30, wherein the first supply contact includes a textured surface conforming to the textured surface of the first doped region.

33. The protection device of claim 30, wherein the second supply contact includes a textured surface conforming to the textured surface of the fourth doped region.

34. The protection device of claim 30, wherein one of the first and second wells includes material of first conductivity type and the other well includes material of second conductivity type.

35. The protection device of claim 30, wherein the first well includes material of first conductivity type and the first and second doped regions include material of second conductivity type.

36. The protection device of claim 35, wherein the second well includes material of second conductivity type and the third and fourth doped regions are made material of first conductivity type.

37. The protection device of claim 36, wherein one of the first and second conductivity types is a P-type and the other conductivity type is an N-type.

38. An integrated circuit comprising:
an internal circuit;
a bonding pad connected to the internal circuit; and
a protection device connected to the bonding pad, the protection device comprising:
a substrate;
a first well and a second well formed in the substrate;
a first doped region and a second doped region formed in the first well, the first doped region connecting to a first supply node, the second doped region connecting to a bonding pad; and
a third doped region and a fourth doped region formed in the second well, the third doped region connecting to the bonding pad, the fourth doped region connecting to a second supply node, wherein each of the first, second, third, and fourth doped regions includes a textured surface.

39. The integrated circuit of claim 38, wherein one of the first and second wells includes material of first conductivity type and the other well includes material of second conductivity type.

40. The integrated circuit of claim 38, wherein the first well includes material of first conductivity type and the first and second doped regions include material of second conductivity type.

41. The integrated circuit of claim 40, wherein the second well includes material of second conductivity type and the third and fourth doped regions are made material of first conductivity type.

42. The integrated circuit of claim 41, wherein one of the first and second conductivity types is a P-type and the other conductivity type is an N-type.

43. The integrated circuit of claim 38, wherein one of the first and second supply nodes has a positive voltage and the other supply node is ground.

44. The integrated circuit of claim 38 further comprising a resistor connected between the first doped region and the first supply node.

45. The integrated circuit of claim 38 further comprising a resistor connected between the fourth doped region and the second supply node.

46. The integrated circuit of claim 38 further comprising:
a first resistor connected between the first doped region and the first supply node; and
a second resistor connected between the fourth doped region and the second supply node.

47. A semiconductor chip comprising:
a package having a plurality of external contacts;
an internal circuit connected to one of the external contacts at an internal node; and
a protection device connected the internal node, the protection device including:
a substrate;
a first well and a second well formed in the substrate;
a first doped region and a second doped region formed in the first well, the first doped region connecting to a first supply node, the second doped region connecting to the internal node; and
a third doped region and a fourth doped region formed in the second well, the third doped region connecting to the internal node, the fourth doped region connecting to a second supply node, wherein each of the first, second, third, and fourth doped regions includes a textured surface.

48. The semiconductor chip of claim 47, wherein one of the first and second wells includes material of first conductivity type and the other well includes material of second conductivity type.

49. The semiconductor chip of claim 47, wherein the first well includes material of first conductivity type and the first and second doped regions include material of second conductivity type.

50. The semiconductor chip of claim 49, wherein the second well includes material of second conductivity type and the third and fourth doped regions are made material of first conductivity type.

51. The semiconductor chip of claim 50, wherein one of the first and second conductivity types is a P-type and the other conductivity type is an N-type.

52. The semiconductor chip of claim 51, wherein one of the first and second supply nodes has a positive voltage and the other supply node is ground.

53. The semiconductor chip of claim 47 further comprising a resistor connected between the first doped region and the first supply node.

54. The semiconductor chip of claim 47 further comprising a resistor connected between the fourth doped region and the second supply node.

55. The semiconductor chip of claim 47 further comprising:
a first resistor connected between the first doped region and the first supply node; and
a second resistor connected between the fourth doped region and the second supply node.

56. A system comprising:
a processor having a plurality of external contacts; and
a memory device connected to the processor and having a plurality external contacts, one of the processor and the memory device including an internal circuit and a protection device connected to one of external contacts at an internal node, the protection device including:
a substrate;
a first well and a second well formed in the substrate;
a first doped region and a second doped region formed in the first well, the first doped region connecting to the internal node, the second doped region connecting to a first supply node; and
a third doped region and a fourth doped region formed in the second well, the third doped region connecting to the internal node, the fourth doped region connecting to a second supply node, wherein each of the first, second, third, and fourth doped regions includes a textured surface.

57. The system of claim 56, wherein one of the first and second wells includes material of first conductivity type and the other well includes material of second conductivity type.

58. The system of claim 57, wherein the first well includes material of first conductivity type and the first and second doped regions include material of second conductivity type.

59. The system of claim 58, wherein the second well includes material of second conductivity type and the third and fourth doped regions are made material of first conductivity type.

60. The system of claim 59, wherein one of the first and second conductivity types is a P-type and the other conductivity type is an N-type.

61. The system of claim 59, wherein one of the first and second supply nodes has a positive voltage and the other supply node is ground.

62. The system of claim 56 further comprising a resistor connected between the first doped region and the first supply node.

63. The system of claim 56 further comprising a resistor connected between the fourth doped region and the second supply node.

64. The system of claim 56 further comprising:
a first resistor connected between the first doped region and the first supply node; and
a second resistor connected between the fourth doped region and the second supply node.

65. A method of forming a transistor, the method comprising:
forming a first doped region in a substrate, the first doped region having an exposed surface;
forming a second doped region in the substrate, the second doped region having an exposed surface; and
texturing the exposed surface of the first doped region and the exposed surface of the second doped region.

66. The method of claim 65, wherein texturing includes etching the exposed surfaces of the first doped and second doped regions to change the shapes of the exposed surfaces to increase surface areas of the exposed surfaces of the first doped and second doped regions.

67. The method of claim 65, further comprising:
forming a first gate on the substrate an separated from the substrate by an insulation layer.

68. The method of claim 67, further comprising:
forming a second gate over the first gate and separated from the first gate by a second insulation layer.

69. The method of claim 65, wherein the substrate and the first doped region include material of first conductivity type, and second doped region includes material of second conductivity type.

70. The device of claim 69, wherein the each of first and second doped regions has a higher doping concentration than the substrate.

71. A method of forming a device, the method comprising:
forming a first well and a second well in a substrate;
forming a first doped region and a second doped region in the first well, each of the first and second doped regions including an exposed surface;
forming a third doped region and a fourth doped region in the second well, each of the third and fourth doped regions including an exposed surface;
texturing the exposed surface of each of the first, second, third, and fourth doped regions to form a first textured surface, a second textured surface, a third textured surface, and a fourth textured surface;
forming a bonding contact on the first and second textured surfaces to connect the first and second doped region together;
forming a first supply contact on the third textured surface; and
forming a second supply contact on the fourth textured surface.

72. The method of claim 71, wherein texturing includes etching the exposed surfaces of the first, second, third, and fourth doped regions to change the shapes of the exposed surfaces to increase surface areas of the exposed surfaces of the first, second, third, and fourth doped regions.

73. The method of claim 71, wherein forming a bonding contact includes forming the bonding contact having a first surface conforming to the first textured surface and a second surface conforming to the second textured surface.

74. The method of claim 71, wherein forming a first supply contact includes forming the first supply contact having a surface conforming to the third textured surface.

75. The method of claim 71, wherein forming a second supply contact includes forming the second supply contact having a surface conforming to the fourth textured surface.

76. A method of forming a device, the method comprising:
forming a first well and a second well in a substrate;
forming a first doped region and a second doped region in the first well, the first and second doped regions being separated by a first channel region, each of the first and second doped regions including an exposed surface;
forming a third doped region and a fourth doped region in the second well, the third and fourth doped regions being separated by a second channel region, each of the third and fourth doped regions including an exposed surface;
forming a first gate opposing the first channel region and separated from the substrate by a first portion of an insulation layer;
forming a second gate opposing the second channel region and separated from the substrate by a second portion of the insulation layer;
texturing the exposed surface of each of the first, second, third, and fourth doped regions to form a first textured surface, a second textured surface, a third textured surface, and a fourth textured surface;
forming a bonding contact on the first and third textured surfaces to connect the first and second doped region together;
forming a first supply contact on the second textured surface; and
forming a second supply contact on the fourth textured surface.

77. The method of claim 76, wherein texturing includes etching the exposed surfaces of the first, second, third, and fourth doped regions to change the shapes of the exposed surfaces to increase surface areas of the exposed surfaces of the first, second, third, and fourth doped regions.

78. The method of claim 76, wherein forming a bonding contact includes forming the bonding contact having a first surface conforming to the first textured surface and a second surface conforming to the second textured surface.

79. The method of claim 76, wherein forming a first supply contact includes forming the first supply contact having a surface conforming to the third textured surface.

80. The method of claim 76, wherein forming a second supply contact includes forming the second supply contact having a surface conforming to the fourth textured surface.
